(19) United States
(12) Patent Application Publication
(10) Pub. No.: US 2017/0291199 A1
(43) Pub. Date: Oct. 12, 2017

(54) FLUORINE REDUCTION WITH SCOPE WITH CONTROLLED OXIDATION

(71) Applicant: Applied Materials, Inc., Santa Clara, CA (US)

(72) Inventors: Xing ZHONG, Foster City, CA (US); Zhijun CHEN, San Jose, CA (US); Zhenjiang CUI, San Jose, CA (US); Nitin K. INGLE, San Jose, CA (US)

(21) Appl. No.: 15/485,105

(22) Filed: Apr. 11, 2017

Related U.S. Application Data
(60) Provisional application No. 62/321,611, filed on Apr. 12, 2016.

(51) Int. Cl. B08B 5/00; H01L 21/02

(52) U.S. Cl. CPC B08B 5/00; H01L 21/0206

(57) ABSTRACT

A method for removing halogen from a surface of a substrate is described herein. The method described herein includes flowing oxygen gas and an inert gas such as nitrogen gas into a RPS. The gases in the RPS are energized to form oxygen radicals and nitrogen radicals. The oxygen and nitrogen radicals are used to remove halogen content on the surface of the substrate. The chamber pressure of the halogen content removal process is very low, ranging from about 50 mTorr to about 100 mTorr. By using oxygen gas and an inert gas and with a low chamber pressure, the halogen content on the surface of the substrate is reduced while keeping the oxidation level of the surface of the substrate to at most 10 Angstroms.

### CROSS-REFERENCE TO RELATED APPLICATIONS

This application claims priority to United States Provisional Patent Application Serial No. 62/321,611, filed on Apr. 12, 2016, which herein is incorporated by reference.

### BACKGROUND

### Field

Embodiments described herein generally relate to a method for processing semiconductor substrates, and more specifically, to a method for removing halogen from a surface of a semiconductor substrate.

### Description of the Related Art

In semiconductor processing, devices are being manufactured with continually decreasing feature dimensions. Often, features utilized to manufacture devices at these advanced technology nodes include high aspect ratio structures such as shallow trench isolation (STI), inter-metal dielectric layers (ILD), pre-metal dielectrics (PMD), passivation layers, patterning applications, etc. The high aspect ratio structures may be formed by a dry etch process using halogen ions and radicals, and residue halogen content may be left on a surface, such as silicon surface of an STI.

Conventionally, wet clean method, such as dilute HF dip, is used for silicon cleaning. However, the limitation of wet clean method is pattern collapse in high aspect ratio structures during the drying step. Dry clean by introducing water vapor into a remote plasma source (RPS) and energizing the water vapor lead to a thick oxide layer formed on the surface due to oxidizing chemistry.

Therefore, an improved method is needed to remove halogen from a surface of the substrate.

### SUMMARY

In one embodiment, a method includes placing a substrate into a processing chamber, flowing an oxygen gas and an inert gas into a remote plasma source coupled to the processing chamber, energizing the oxygen gas and the inert gas to form radicals, flowing the radicals into the processing chamber, and removing halogen content on a surface of the substrate using the radicals. An oxide layer is formed on the surface of the substrate, and the oxide layer has a thickness of at most 10 Angstroms.

In another embodiment, a method includes placing a substrate into a processing chamber, flowing an oxygen gas and a nitrogen gas into a remote plasma source coupled to the processing chamber, energizing the oxygen gas and the nitrogen gas to form radicals, flowing the radicals into the processing chamber, and maintaining a pressure inside the processing chamber. The pressure ranges from about 50 mTorr to about 100 mTorr. The method further includes removing halogen content on a surface of the substrate using the radicals. An oxide layer is formed on the surface of the substrate, and the oxide layer has a thickness of at most 10 Angstroms.

In another embodiment, a method includes placing a substrate into a processing chamber, flowing an oxygen gas and a nitrogen gas into a remote plasma source coupled to the processing chamber, energizing the oxygen gas and the nitrogen gas to form radicals, flowing the radicals into the processing chamber, and removing halogen content on a surface of the substrate using the radicals. An oxide layer is formed on the surface of the substrate, and the oxide layer has a thickness of at most 10 Angstroms.

### BRIEF DESCRIPTION OF THE DRAWINGS

FIG. 1 is a flow diagram of a method for removing halogen content from a surface of a substrate according to one embodiment described herein.

FIG. 2A is a chart showing oxide layer thickness as a result of various processes according to one embodiment described herein.

FIG. 2B is a chart showing fluorine content on the surface of the substrate as a result of various processes according to one embodiment described herein.

To facilitate understanding, identical reference numerals have been used, wherever possible, to designate identical elements that are common to the Figures. Additionally, elements of one aspect may be advantageously adapted for utilization in other aspects described herein.

### DETAILED DESCRIPTION

A method for removing halogen from a surface of a substrate is described herein. The method described herein includes flowing oxygen gas and an inert gas such as nitrogen gas into a RPS. The gases in the RPS are energized to form oxygen radicals and nitrogen radicals. The oxygen and nitrogen radicals are used to remove halogen content on the surface of the substrate. The chamber pressure of the halogen content removal process is very low, ranging from about 50 mTorr to about 100 mTorr. By using oxygen gas and an inert gas and with a low chamber pressure, the halogen content on the surface of the substrate is reduced while keeping the oxidation level of the surface of the substrate to at most 10 Angstroms.

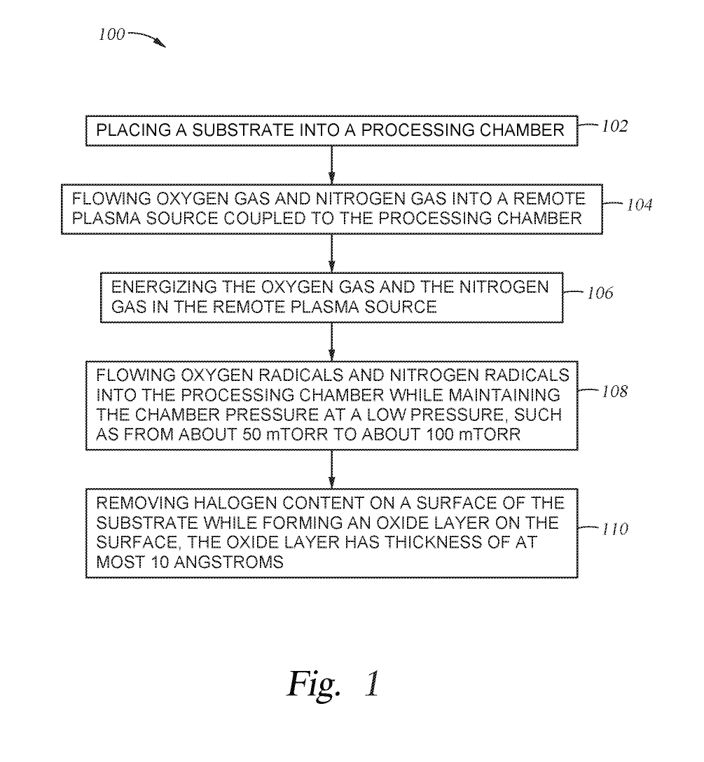

FIG. 1 is a flow diagram of a method 100 for removing halogen content from a surface of a substrate according to one embodiment described herein. At block 102, a substrate is placed into a processing chamber. The substrate may include high aspect ratio structures, such as STIs, disposed thereon. Prior processes performed on the high aspect ratio structures may leave halogen content, such as fluorine radicals, on the surface of the substrate. The processing chamber may be a loadlock chamber having a RPS coupled thereto.

Next, at block 104, an oxygen gas (O₂) and a nitrogen gas (N₂) are flowed into the RPS. The ratio of the flow rates of the oxygen gas to the nitrogen gas may range from five to one to 20 to one. In one embodiment, the flow rate of the oxygen gas ranges from about 500 to 2000 standard cubic centimeters per minute (sccm) and the flow rate of the nitrogen gas ranges from about 100 to 500 sccm. In some embodiments, an inert gas other than nitrogen gas may be used. The inert gas may be argon gas or helium gas. In one embodiment, water vapor is flowed to the RPS along with oxygen gas. The RPS may be operated at up to 2000 W, such as from about 100 W to about 2000 W.

Next, at block 106, the energized species, such as oxygen radicals and nitrogen radicals, are flowed into the processing chamber. The processing chamber may be maintained at low pressure, such as from about 50 mTorr to about 100 mTorr. The substrate may be heated by a substrate support, and the substrate support may be maintained at about 60 to 300 degrees Celsius, such as about 85 degrees Celsius.

Next, at block 108, the halogen content on the substrate surface is removed by the oxygen radicals and nitrogen radicals. It is believed at a low pressure, the mean-free path of the oxygen radicals is longer. Also at low pressure the oxygen radicals is more active. More active radicals with longer mean-free path will attack the surface of the substrate more aggressively.

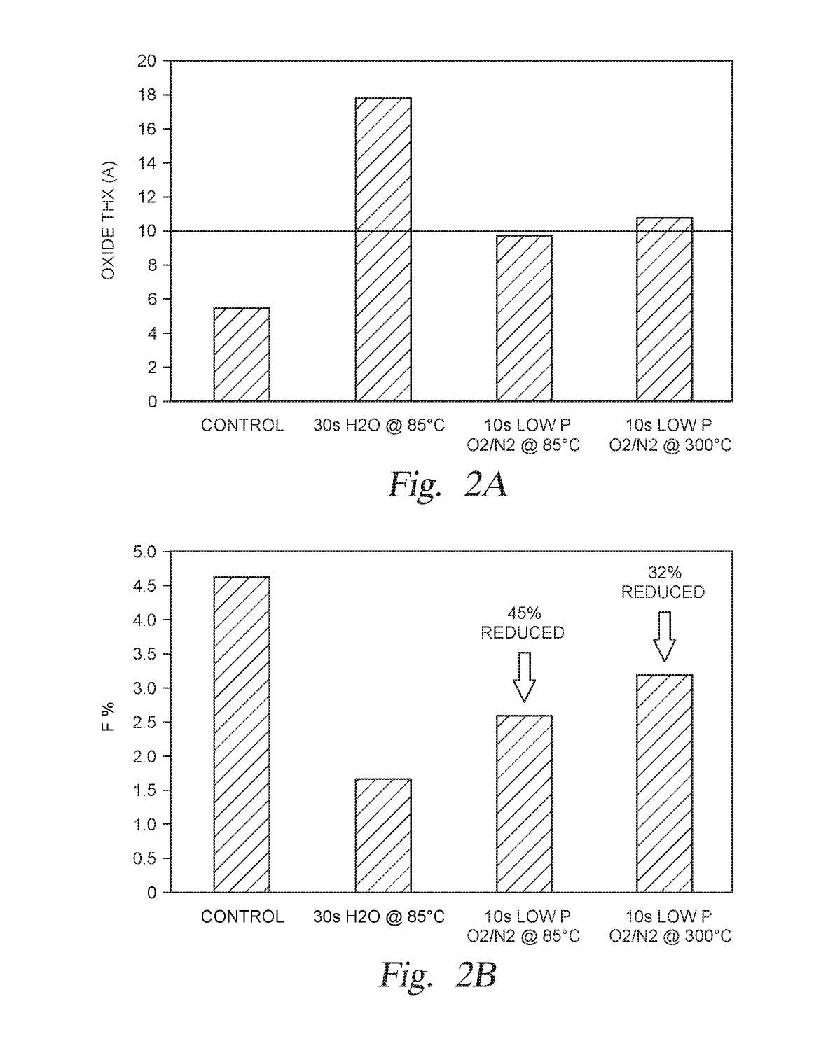

FIG. 2A is a chart showing oxide layer thickness as a result of various processes according to one embodiment described herein. As shown in FIG. 2A, other than the control group, which does not include the process of removing halogen content, oxygen gas and nitrogen gas combination at 85 degrees Celsius shows thinnest oxide layer.

FIG. 2B is a chart showing fluorine content on the surface of the substrate as a result of various processes according to one embodiment described herein. As shown in FIG. 2B, other than the control group, which does not include the process of removing halogen content, oxygen gas and nitrogen gas combination at 85 degrees Celsius shows a 45 percent reduction in fluorine content on the surface of the substrate.

While the foregoing is directed to embodiments of the present disclosure, other and further embodiments of the disclosure may be devised without departing from the basic scope thereof, and the scope thereof is determined by the claims that follow.

1. A method, comprising:
placing a substrate into a processing chamber;
flowing an oxygen gas and an inert gas into a remote plasma source coupled to the processing chamber;
energizing the oxygen gas and the inert gas to form radicals;
flowing the radicals into the processing chamber; and
removing halogen content on a surface of the substrate using the radicals, wherein an oxide layer is formed on the surface of the substrate, and the oxide layer has a thickness of at most 10 Angstroms.

2. The method of claim 1, wherein the processing chamber is a loadlock chamber.

3. The method of claim 1, wherein the substrate is heated by a substrate support located in the processing chamber.

4. The method of claim 3, wherein the substrate support is maintained at a temperature ranging from about 60 degrees Celsius to about 300 degrees Celsius.

5. The method of claim 4, wherein the substrate support is maintained at a temperature of about 85 degrees Celsius.

6. The method of claim 1, wherein the oxygen gas is flowed into the remote plasma source at a flow rate ranging from about 500 to about 2000 standard cubic centimeters per minute.

7. The method of claim 1, wherein the inert gas is flowed into the remote plasma source at a flow rate ranging from about 100 to about 500 standard cubic centimeters per minute.

8. The method of claim 1, wherein the inert gas comprises nitrogen gas, argon gas, or helium gas.

9. A method, comprising:
placing a substrate into a processing chamber;
flowing an oxygen gas and a nitrogen gas into a remote plasma source coupled to the processing chamber;
energizing the oxygen gas and the nitrogen gas to form radicals;
flowing the radicals into the processing chamber;
maintaining a pressure inside the processing chamber, wherein the pressure ranges from about 50 mTorr to about 100 mTorr; and
removing halogen content on a surface of the substrate using the radicals, wherein an oxide layer is formed on the surface of the substrate, and the oxide layer has a thickness of at most 10 Angstroms.

10. The method of claim 9, wherein the processing chamber is a loadlock chamber.

11. The method of claim 9, wherein the substrate is heated by a substrate support located in the processing chamber.

12. The method of claim 11, wherein the substrate support is maintained at a temperature ranging from about 60 degrees Celsius to about 300 degrees Celsius.

13. The method of claim 12, wherein the substrate support is maintained at a temperature of about 85 degrees Celsius.

14. The method of claim 9, wherein the oxygen gas is flowed into the remote plasma source at a flow rate ranging from about 500 to about 2000 standard cubic centimeters per minute.

15. The method of claim 9, wherein the inert gas is flowed into the remote plasma source at a flow rate ranging from about 100 to about 500 standard cubic centimeters per minute.

16. The method of claim 9, wherein the inert gas comprises nitrogen gas, argon gas, or helium gas.

17. A method, comprising:
placing a substrate into a processing chamber;
flowing an oxygen gas and a nitrogen gas into a remote plasma source coupled to the processing chamber;
energizing the oxygen gas and the nitrogen gas to form radicals;
flowing the radicals into the processing chamber; and
removing halogen content on a surface of the substrate using the radicals, wherein an oxide layer is formed on the surface of the substrate, and the oxide layer has a thickness of at most 10 Angstroms.

18. The method of claim 17, wherein the processing chamber is a loadlock chamber.

19. The method of claim 17, wherein the substrate is heated by a substrate support located in the processing chamber.

20. The method of claim 19, wherein the substrate support is maintained at a temperature ranging from about 60 degrees Celsius to about 300 degrees Celsius.
